(19) United States
(12) Patent Application Publication
(10) Pub. No.: US 2011/0114925 A1
(43) Pub. Date: May 19, 2011

(54) BUFFER BILAYERS FOR ELECTRONIC DEVICES

(76) Inventors: Che-Hsiung Hsu, Wilmington, DE (US); Weiying Gao, Landenberg, PA (US)

(21) Appl. No.: 12/809,895

(22) PCT Filed: Dec. 23, 2008
(86) PCT No.: PCT/US08/88089

§ 371 Date: Jan. 24, 2011

Related U.S. Application Data
(60) Provisional application No. 61/016,851, filed on Dec. 27, 2007.

(51) Int. Cl. H01L 51/52; B32B 27/06

(52) U.S. Cl. 257/40; 428/422; 428/688; 428/206; 428/419; 428/421; 428/696; 428/446; 428/447; 257/E51.018

(57) ABSTRACT

The present disclosure relates to buffer bilayers, and their use in electronic devices. The bilayer has a first layer including at least one electrically conductive polymer doped with at least one highly-fluorinated acid polymer, and a second layer including inorganic nanoparticles.

### RELATED APPLICATION DATA

This application claims priority under 35 U.S.C. §119(e) from U.S. Provisional Application No. 61/016,851 filed on Dec. 27, 2007, which is incorporated by reference herein in its entirety.

### BACKGROUND INFORMATION

1. Field of the Disclosure

This disclosure relates in general to buffer bilayers and their use in electronic devices.

2. Description of the Related Art

Electronic devices define a category of products that include an active layer. Organic electronic devices have at least one organic active layer. Such devices convert electrical energy into radiation such as light emitting diodes, detect signals through electronic processes, convert radiation into electrical energy, such as photovoltaic cells, or include one or more organic semiconductor layers.

Organic light-emitting diodes (OLEDs) are an organic electronic device comprising an organic layer capable of electroluminescence. OLEDs containing conducting polymers can have the following configuration:

anode/buffer layer/EL material/cathode

with additional layers between the electrodes. The anode is typically any material that has the ability to inject holes into the EL material, such as, for example, indium/tin oxide (ITO). The anode is optionally supported on a glass or plastic substrate. EL materials include fluorescent compounds, fluorescent and phosphorescent metal complexes, conjugated polymers, and mixtures thereof. The cathode is typically any material (such as, e.g., Ca or Ba) that has the ability to inject electrons into the EL material. Electrically conducting polymers having low conductivity in the range of 10⁻³ to 10⁻⁷ S/cm are commonly used as the buffer layer in direct contact with an electrically conductive anode, such as ITO.

There is a continuing need for improved buffer layers.

### SUMMARY

There is provided a buffer bilayer comprising:
a first layer comprising at least one electrically conductive polymer doped with at least one highly-fluorinated acid polymer, and
a second layer in contact with the first layer, the second layer comprising inorganic nanoparticles selected from the group consisting of oxides, sulfides, and combinations thereof.

In another embodiment, the second layer is a discontinuous layer.

In another embodiment, electronic devices comprising at least one buffer bilayer are provided.

### BRIEF DESCRIPTION OF THE DRAWINGS

The invention is illustrated by way of example and not limitation in the accompanying figures.

FIG. 1 is a diagram illustrating contact angle.

FIG. 2 is a schematic diagram of one example of an organic electronic device.

FIG. 3 is a schematic diagram of another example of an organic electronic device.

Skilled artisans will appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

Many aspects and embodiments are described herein and are merely exemplary and not limiting. After reading this specification, skilled artisans will appreciate that other aspects and embodiments are possible without departing from the scope of the invention.

Other features and benefits of any one or more of the embodiments will be apparent from the following detailed description, and from the claims. The detailed description first addresses Definitions and Clarification of Terms followed by the First Layer of the Buffer Bilayer, the Second Layer of the Buffer Bilayer, the Formation of the Buffer Bilayer, Electronic Devices, and finally, Examples.

### 1. Definitions and Clarification of Terms

Before addressing details of embodiments described below, some terms are defined or clarified.

The term “buffer layer” or “buffer material” is intended to refer to electrically conductive or semiconductive layers or materials which may have one or more functions in an organic electronic device, including but not limited to, planarization of the underlying layer, charge transport and/or charge injection properties, scavenging of impurities such as oxygen or metal ions, and other aspects to facilitate or to improve the performance of an organic electronic device.

The term “conductor” and its variants are intended to refer to a layer material, member, or structure having an electrical property such that current flows through such layer material, member, or structure without a substantial drop in potential. The term is intended to include semiconductors. In some embodiments, a conductor will form a layer having a conductivity of at least 10⁻⁷ S/cm.

The term “discontinuous” as it refers to a layer, is intended to mean a layer that does not completely cover the underlying layer in the areas in which it is applied.

The term “electrically conductive” as it refers to a material, is intended to mean a material which is inherently or intrinsically capable of electrical conductivity without the addition of carbon black or conductive metal particles.

The term “polymer” is intended to mean a material having at least one repeating monomeric unit. The term includes homopolymers having only one kind, or species, of monomeric unit, and copolymers having two or more different monomeric units, including copolymers formed from monomeric units of different species.

The term “acid polymer” refers to a polymer having acidic groups.

The term “acidic group” refers to a group capable of ionizing to donate a hydrogen ion to a Brønsted base.

The term “highly-fluorinated” refers to a compound in which at least 90% of the available hydrogens bonded to carbon have been replaced by fluorine.

The terms “fully-fluorinated” and “perfluorinated” are used interchangeably and refer to a compound where all of the available hydrogens bonded to carbon have been replaced by fluorine.

The term “doped” as it refers to an electrically conductive polymer, is intended to mean that the electrically conductive polymer has a polymeric counterion to balance the charge on the conductive polymer.

The term “doped conductive polymer” is intended to mean the conductive polymer and the polymeric counterion that is associated with it.

The term “layer” is used interchangeably with the term “film” and refers to a coating covering a desired area. The term is not limited by size. The area can be as large as an entire device or as small as a specific functional area such as the actual visual display, or as small as a single sub-pixel. Unless otherwise indicated, layers and films can be formed by any conventional deposition technique, including vapor deposition, liquid deposition (continuous and discontinuous techniques), and thermal transfer.

The term “nanoparticle” refers to a material having a particle size less than 100 nm. In some embodiments, the particle size is less than 10 nm. In some embodiments, the particle size is less than 5 nm.

The term “aqueous” refers to a liquid that has a significant portion of water, and in one embodiment it is at least about 40% by weight water; in some embodiments, at least about 60% by weight water.

The term “hole transport” when referring to a layer, material, member, or structure, is intended to mean such layer, material, member, or structure facilitates migration of positive charges through the thickness of such layer, material, member, or structure with relative efficiency and small loss of charge.

The term “electron transport” means when referring to a layer, material, member or structure, such a layer, material, member or structure that promotes or facilitates migration of negative charges through such a layer, material, member or structure into another layer, material, member or structure.

The term “organic electronic device” is intended to mean a device including one or more semiconductor layers or materials. Organic electronic devices include, but are not limited to: (1) devices that convert electrical energy into radiation (e.g., a light-emitting diode, light emitting diode display, diode laser, or lighting panel), (2) devices that detect signals through electronic processes (e.g., photodetectors photoconductive cells, photoresistors, photoswitches, phototransistors, phototubes, infrared (“IR”) detectors, or biosensors), (3) devices that convert radiation into electrical energy (e.g., a photovoltaic device or solar cell), and (4) devices that include one or more electronic components that include one or more organic semiconductor layers (e.g., a transistor or diode).

Although light-emitting materials may also have some charge transport properties, the terms “hole transport” and “electron transport” are not intended to include a layer, material, member, or structure whose primary function is light emission.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Group numbers corresponding to columns within the Periodic Table of the elements use the “New Notation” convention as seen in the CRC Handbook of Chemistry and Physics, 81^{st} Edition (2000-2001).

Unless otherwise defined, all technical and scientific terms used herein have the same meaning as commonly understood by one of ordinary skill in the art to which this invention belongs. In the Formulae, the letters Q, R, T, W, X, Y, and Z are used to designate atoms or groups which are defined within. All other letters are used to designate conventional atomic symbols. Group numbers corresponding to columns within the Periodic Table of the elements use the “New Notation” convention as seen in the CRC Handbook of Chemistry and Physics, 81^{st} Edition (2000).

To the extent not described herein, many details regarding specific materials, processing acts, and circuits are conventional and may be found in textbooks and other sources within the organic light-emitting diode display, lighting source, photodetector, photovoltaic, and semiconductive member arts.

### 2. First Layer of the Buffer Bilayer

The first layer comprises a conductive polymer doped with a highly-fluorinated acid polymer. The layer may comprise one or more different electrically conductive polymers and one or more different highly-fluorinated acid polymers. In some embodiments, the first layer consists essentially of a conductive polymer doped with a highly-fluorinated acid polymer.

a. Electrically Conductive Polymer

Any electrically conductive polymer can be used in the new composition. In some embodiments, the electrically conductive polymer will form a film which has a conductivity greater than 10⁻⁷ S/cm.

The conductive polymers suitable for the new composition are made from at least one monomer which, when polymerized alone, forms an electrically conductive homopolymer. Such monomers are referred to herein as “conductive precursor monomers.” Monomers which, when polymerized alone form homopolymers which are not electrically conductive, are referred to as “non-conductive precursor monomers.” The conductive polymer can be a homopolymer or a copolymer. Conductive copolymers suitable for the new composition can be made from two or more conductive precursor monomers or from a combination of one or more conductive precursor monomers and one or more non-conductive precursor monomers.

In some embodiments, the conductive polymer is made from at least one precursor monomer selected from thiophenes, selenophenes, tellurophenes, pyrroles, anilines, 4-amino-indoles, 7-amino-indoles, and polycyclic aromatics. The polymers made from these monomers are referred to herein as polythiophenes, poly(selenophenes), poly(tellurophenes), polypyrroles, polyanilines, poly(4-amino-indoles), poly(7-amino-indoles), and polycyclic aromatic polymers, respectively. The term “polycyclic aromatic” refers to compounds having more than one aromatic ring. The rings may be joined by one or more bonds, or they may be fused together. The term “aromatic ring” is intended to include heteroaromatic rings. A “polycyclic heteroaromatic” compound has at least one heteroaromatic ring. In some embodiments, the polycyclic aromatic polymers are poly(thienothiophenes).

In some embodiments, monomers contemplated for use to form the electrically conductive polymer in the new composition comprise Formula I below:

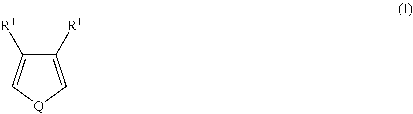

wherein:
Q is selected from the group consisting of S, Se, and Te;
R¹ is independently selected so as to be the same or different at each occurrence and is selected from hydrogen, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, cyano, hydroxyl, epoxy, silane, siloxane, alcohol, benzyl, carboxylate, ether, ether carboxylate, amidosulfonate, ether sulfonate, ester sulfonate, and urethane; or both R¹ groups together may form an alkylene or alkenylene chain completing a 3, 4, 5, 6, or 7-membered aromatic or alicyclic ring, which ring may optionally include one or more divalent nitrogen, selenium, tellurium, sulfur or oxygen atoms.

As used herein, the term “alkyl” refers to a group derived from an aliphatic hydrocarbon and includes linear, branched and cyclic groups which may be unsubstituted or substituted. The term “heteroalkyl” is intended to mean an alkyl group, wherein one or more of the carbon atoms within the alkyl group has been replaced by another atom, such as nitrogen, oxygen, sulfur, and the like. The term “alkylene” refers to an alkyl group having two points of attachment.

As used herein, the term “alkenyl” refers to a group derived from an aliphatic hydrocarbon having at least one carbon-carbon double bond, and includes linear, branched and cyclic groups which may be unsubstituted or substituted. The term “heteroalkenyl” is intended to mean an alkenyl group, wherein one or more of the carbon atoms within the alkenyl group has been replaced by another atom, such as nitrogen, oxygen, sulfur, and the like. The term “alkenylene” refers to an alkenyl group having two points of attachment.

As used herein, the following terms for substituent groups refer to the formulae given below:

| | |
|---|---|
| “alcohol” | —R³—OH |
| “amido” | —R³—C(O)N(R⁶) R⁶ |
| “amidosulfonate” | —R³—C(O)N(R⁶) R⁴—SO₃Z |
| “benzyl” | —CH₂—C₆H₅ |
| “carboxylate” | —R³—C(O)O—Z or —R³—O—C(O)—Z |
| “ether” | —R³—(O—R⁵)ₚ—O—R⁵ |
| “ether carboxylate” | —R³—O—R⁴—C(O)O—Z or |
| | —R³—O—R⁴—O—C(O)—Z |
| “ether sulfonate” | —R³—O—R⁴—SO₃Z |
| “ester sulfonate” | —R³—O—C(O)—R⁴—SO₃Z |
| “sulfonimide” | —R³—SO₂—NH—SO₂—R⁵ |
| “urethane” | —R³—O—C(O)—N(R⁶)₂ |

where all “R” groups are the same or different at each occurrence and:
R³ is a single bond or an alkylene group
R⁴ is an alkylene group
R⁵ is an alkyl group
R⁶ is hydrogen or an alkyl group
p is 0 or an integer from 1 to 20
Z is H, alkali metal, alkaline earth metal, N(R⁵)₄ or R⁵
   Any of the above groups may further be unsubstituted or substituted, and any group may have F substituted for one or more hydrogens, including perfluorinated groups. In some embodiments, the alkyl and alkylene groups have from 1-20 carbon atoms.

In some embodiments, in the monomer, both R¹ together form —W—(CY¹Y²)ₘ-W—, where m is 2 or 3, W is O, S, Se, PO, NR⁶, Y¹ is the same or different at each occurrence and is hydrogen or fluorine, and Y² is the same or different at each occurrence and is selected from hydrogen, halogen, alkyl, alcohol, amidosulfonate, benzyl, carboxylate, ether, ether carboxylate, ether sulfonate, ester sulfonate, and urethane, where the Y groups may be partially or fully fluorinated. In some embodiments, all Y are hydrogen. In some embodiments, the polymer is poly(3,4-ethylenedioxythiophene). In some embodiments, at least one Y group is not hydrogen. In some embodiments, at least one Y group is a substituent having F substituted for at least one hydrogen. In some embodiments, at least one Y group is perfluorinated.

In some embodiments, the monomer has Formula I(a):

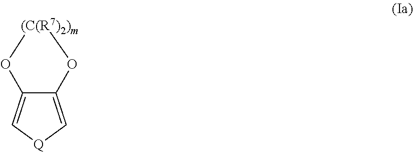

wherein:
Q is selected from the group consisting of S, Se, and Te;
R⁷ is the same or different at each occurrence and is selected from hydrogen, alkyl, heteroalkyl, alkenyl, heteroalkenyl, alcohol, amidosulfonate, benzyl, carboxylate, ether, ether carboxylate, ether sulfonate, ester sulfonate, and urethane, with the proviso that at least one R⁷ is not hydrogen, and
m is 2 or 3.

In some embodiments of Formula I(a), m is two, one R⁷ is an alkyl group of more than 5 carbon atoms, and all other R⁷ are hydrogen. In some embodiments of Formula I(a), at least one R⁷ group is fluorinated. In some embodiments, at least one R⁷ group has at least one fluorine substituent. In some embodiments, the R⁷ group is fully fluorinated.

In some embodiments of Formula I(a), the R⁷ substituents on the fused alicyclic ring on the monomer offer improved solubility of the monomers in water and facilitate polymerization in the presence of the fluorinated acid polymer.

In some embodiments of Formula I(a), m is 2, one R⁷ is sulfonic acid-propylene-ether-methylene and all other R⁷ are hydrogen. In some embodiments, m is 2, one R⁷ is propyl-ether-ethylene and all other R⁷ are hydrogen. In some embodiments, m is 2, one R⁷ is methoxy and all other R⁷ are hydrogen. In some embodiments, one R⁷ is sulfonic acid difluoromethylene ester methylene (—CH₂—O—C(O)—CF₂—SO₃H), and all other R⁷ are hydrogen.

In some embodiments, pyrrole monomers contemplated for use to form the electrically conductive polymer in the new composition comprise Formula II below.

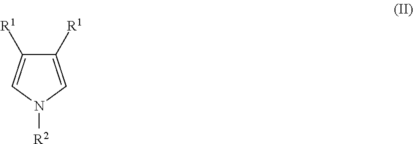

where in Formula II:
R¹ is independently selected so as to be the same or different at each occurrence and is selected from hydrogen, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, cyano, hydroxyl, epoxy, silane, siloxane, alcohol, benzyl, carboxylate, ether, amidosulfonate, ether carboxylate, ether sulfonate, ester sulfonate, and urethane; or both R¹ groups together may form an alkylene or alkenylene chain completing a 3, 4, 5, 6, or 7-membered aromatic or alicyclic ring, which ring may optionally include one or more divalent nitrogen, sulfur, selenium, tellurium, or oxygen atoms; and
R² is independently selected so as to be the same or different at each occurrence and is selected from hydrogen, alkyl, alkenyl, aryl, alkanoyl, alkylthioalkyl, alkylaryl, arylalkyl, amino, epoxy, silane, siloxane, alcohol, benzyl, carboxylate, ether, ether carboxylate, ether sulfonate, ester sulfonate, and urethane.

In some embodiments, R¹ is the same or different at each occurrence and is independently selected from hydrogen, alkyl, alkenyl, alkoxy, cycloalkyl, cycloalkenyl, alcohol, benzyl, carboxylate, ether, amidosulfonate, ether carboxylate, ether sulfonate, ester sulfonate, urethane, epoxy, silane, siloxane, and alkyl substituted with one or more of sulfonic acid, carboxylic acid, acrylic acid, phosphoric acid, phosphonic acid, halogen, nitro, cyano, hydroxyl, epoxy, silane, or siloxane moieties.

In some embodiments, R² is selected from hydrogen, alkyl, and alkyl substituted with one or more of sulfonic acid, carboxylic acid, acrylic acid, phosphoric acid, phosphonic acid, halogen, cyano, hydroxyl, epoxy, silane, or siloxane moieties.

In some embodiments, the pyrrole monomer is unsubstituted and both R¹ and R² are hydrogen.

In some embodiments, both R¹ together form a 6- or 7-membered alicyclic ring, which is further substituted with a group selected from alkyl, heteroalkyl, alcohol, benzyl, carboxylate, ether, ether carboxylate, ether sulfonate, ester sulfonate, and urethane. These groups can improve the solubility of the monomer and the resulting polymer. In some embodiments, both R¹ together form a 6- or 7-membered alicyclic ring, which is further substituted with an alkyl group. In some embodiments, both R¹ together form a 6- or 7-membered alicyclic ring, which is further substituted with an alkyl group having at least 1 carbon atom.

In some embodiments, both R¹ together form —O—(CHY)ₘ-O—, where m is 2 or 3, and Y is the same or different at each occurrence and is selected from hydrogen, alkyl, alcohol, benzyl, carboxylate, amidosulfonate, ether, ether carboxylate, ether sulfonate, ester sulfonate, and urethane. In some embodiments, at least one Y group is not hydrogen. In some embodiments, at least one Y group is a substituent having F substituted for at least one hydrogen. In some embodiments, at least one Y group is perfluorinated.

In some embodiments, aniline monomers contemplated for use to form the electrically conductive polymer in the new composition comprise Formula III below.

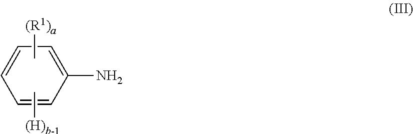

wherein:
a is 0 or an integer from 1 to 4;
b is an integer from 1 to 5, with the proviso that a+b=5; and R¹ is independently selected so as to be the same or different at each occurrence and is selected from hydrogen, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, cyano, hydroxyl, epoxy, silane, siloxane, alcohol, benzyl, carboxylate, ether, ether carboxylate, amidosulfonate, ether sulfonate, ester sulfonate, and urethane; or both R¹ groups together may form an alkylene or alkenylene chain completing a 3, 4, 5, 6, or 7-membered aromatic or alicyclic ring, which ring may optionally include one or more divalent nitrogen, sulfur or oxygen atoms.

When polymerized, the aniline monomeric unit can have Formula IV(a) or Formula IV(b) shown below, or a combination of both formulae.

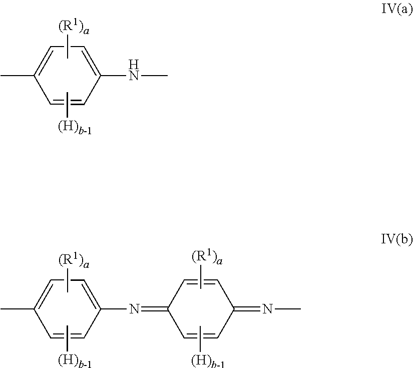

where a, b and R¹ are as defined above.

In some embodiments, the aniline monomer is unsubstituted and a=0.

In some embodiments, a is not 0 and at least one R¹ is fluorinated. In some embodiments, at least one R¹ is perfluorinated.

In some embodiments, fused polycyclic heteroaromatic monomers contemplated for use to form the electrically conductive polymer in the new composition have two or more fused aromatic rings, at least one of which is heteroaromatic. In some embodiments, the fused polycyclic heteroaromatic monomer has Formula V:

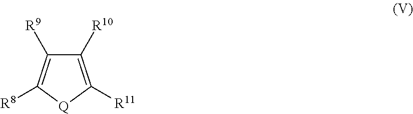

wherein:
Q is S, Se, Te, or NR⁶;
R⁶ is hydrogen or alkyl;
R⁸, R⁹, R¹⁰, and R¹¹ are independently selected so as to be the same or different at each occurrence and are selected from hydrogen, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, nitrile, cyano, hydroxyl, epoxy, silane, siloxane, alcohol, benzyl, carboxylate, ether, ether carboxylate, amidosulfonate, ether sulfonate, ester sulfonate, and urethane; and
at least one of R⁸ and R⁹, R⁹ and R¹⁰, and R¹⁰ and R¹¹ together form an alkenylene chain completing a 5 or 6-membered aromatic ring, which ring may optionally include one or more divalent nitrogen, sulfur, selenium, tellurium, or oxygen atoms.

In some embodiments, the fused polycyclic heteroaromatic monomer has a formula selected from the group consisting of Formula V(a), V(b), V(c), V(d), V(e), V(f), V(g), V(h), V(i), V(j), and V(k):

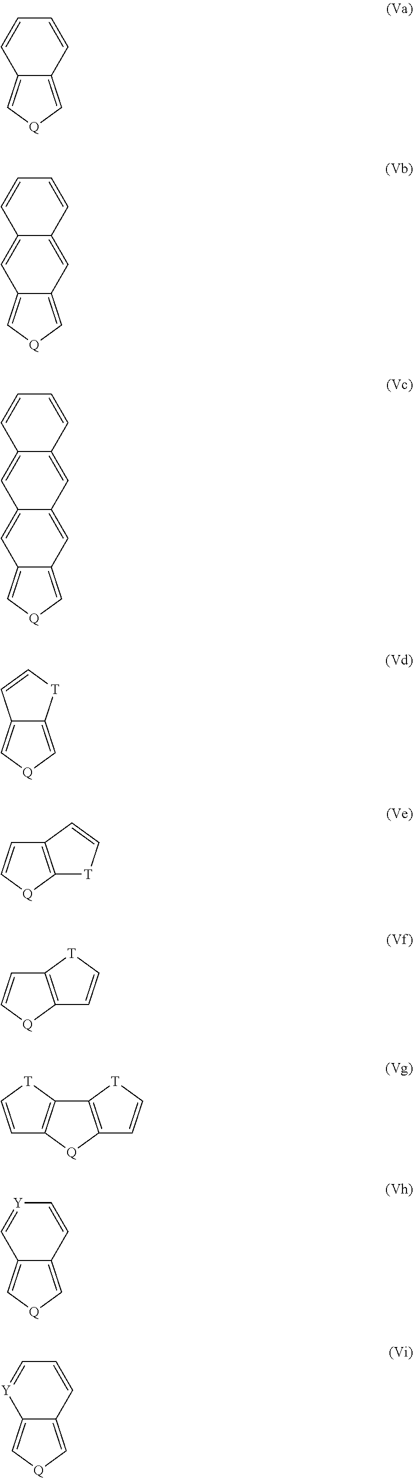

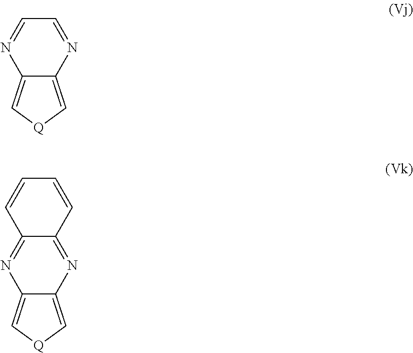

wherein:
Q is S, Se, Te, or NH; and
T is the same or different at each occurrence and is selected from S, NR⁶, O, SiR⁶₂, Se, Te, and PR⁶;
Y is N; and
R⁶ is hydrogen or alkyl.
   The fused polycyclic heteroaromatic monomers may be further substituted with groups selected from alkyl, heteroalkyl, alcohol, benzyl, carboxylate, ether, ether carboxylate, ether sulfonate, ester sulfonate, and urethane. In some embodiments, the substituent groups are fluorinated. In some embodiments, the substituent groups are fully fluorinated.

In some embodiments, the fused polycyclic heteroaromatic monomer is a thieno(thiophene). Such compounds have been discussed in, for example, Macromolecules, 34, 5746-5747 (2001); and Macromolecules, 35, 7281-7286 (2002). In some embodiments, the thieno(thiophene) is selected from thieno(2,3-b)thiophene, thieno(3,2-b)thiophene, and thieno(3,4-b)thiophene. In some embodiments, the thieno(thiophene) monomer is further substituted with at least one group selected from alkyl, heteroalkyl, alcohol, benzyl, carboxylate, ether, ether carboxylate, ether sulfonate, ester sulfonate, and urethane. In some embodiments, the substituent groups are fluorinated. In some embodiments, the substituent groups are fully fluorinated.

In some embodiments, polycyclic heteroaromatic monomers contemplated for use to form the polymer in the new composition comprise Formula VI:

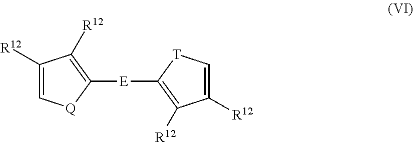

wherein:
Q is S, Se, Te, or NR⁶;
T is selected from S, NR⁶, O, SiR⁶₂, Se, Te, and PR⁶;
E is selected from alkenylene, arylene, and heteroarylene;
R⁶ is hydrogen or alkyl;
   R¹² is the same or different at each occurrence and is selected from hydrogen, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, nitrile, cyano, hydroxyl, epoxy, silane, siloxane, alcohol, benzyl, carboxylate, ether, ether carboxylate, amidosulfonate, ether sulfonate, ester sulfonate, and urethane; or both R¹² groups together may form an alkylene or alkenylene chain completing a 3, 4, 5, 6, or 7-membered aromatic or alicyclic ring, which ring may optionally include one or more divalent nitrogen, sulfur, selenium, tellurium, or oxygen atoms.

In some embodiments, the electrically conductive polymer is a copolymer of a precursor monomer and at least one second monomer. Any type of second monomer can be used, so long as it does not detrimentally affect the desired properties of the copolymer. In some embodiments, the second monomer comprises no more than 50% of the polymer, based on the total number of monomer units. In some embodiments, the second monomer comprises no more than 30%, based on the total number of monomer units. In some embodiments, the second monomer comprises no more than 10%, based on the total number of monomer units.

Exemplary types of second monomers include, but are not limited to, alkenyl, alkynyl, arylene, and heteroarylene. Examples of second monomers include, but are not limited to, fluorene, oxadiazole, thiadiazole, benzothiadiazole, phenylenevinylene, phenyleneethynylene, pyridine, diazines, and triazines, all of which may be further substituted.

In some embodiments, the copolymers are made by first forming an intermediate precursor monomer having the structure A-B-C, where A and C represent precursor monomers, which can be the same or different, and B represents a second monomer. The A-B-C intermediate precursor monomer can be prepared using standard synthetic organic techniques, such as Yamamoto, Stille, Grignard metathesis, Suzuki, and Negishi couplings. The copolymer is then formed by oxidative polymerization of the intermediate precursor monomer alone, or with one or more additional precursor monomers.

In some embodiments, the electrically conductive polymer is selected from the group consisting of a polythiophene, a polypyrrole, a polymeric fused polycyclic heteroaromatic, a copolymer thereof, and combinations thereof.

In some embodiments, the electrically conductive polymer is selected from the group consisting of poly(3,4-ethylenedioxythiophene), poly(3,4-ethyleneoxythiathiophene), poly(3,4-ehtylenedithiathiophene), unsubstituted polypyrrole, poly(thieno(2,3-b)thiophene), poly(thieno(3,2-b)thiophene), and poly(thieno(3,4-b)thiophene).

b. Highly-fluorinated Acid Polymer

The highly-fluorinated acid polymer (“HFAP”) can be any polymer which is highly-fluorinated and has acidic groups with acidic protons. The acidic groups supply an ionizable proton. In some embodiments, the acidic proton has a pKa of less than 3. In some embodiments, the acidic proton has a pKa of less than 0. In some embodiments, the acidic proton has a pKa of less than −5. The acidic group can be attached directly to the polymer backbone, or it can be attached to side chains on the polymer backbone. Examples of acidic groups include, but are not limited to, carboxylic acid groups, sulfonic acid groups, sulfonimide groups, phosphoric acid groups, phosphonic acid groups, and combinations thereof. The acidic groups can all be the same, or the polymer may have more than one type of acidic group. In some embodiments, the acidic groups are selected from the group consisting of sulfonic acid groups, sulfonamide groups, and combinations thereof.

In some embodiments, the HFAP is at least 95% fluorinated; in some embodiments, fully-fluorinated.

In some embodiments, the HFAP is water-soluble. In some embodiments, the HFAP is dispersible in water. In some embodiments, the HFAP is organic solvent wettable. The term “organic solvent wettable” refers to a material which, when formed into a film, possesses a contact angle no greater than 60° C. with organic solvents. In some embodiments, wettable materials form films which are wettable by phenylhexane with a contact angle no greater than 55°. The methods for measuring contact angles are well known. In some embodiments, the wettable material can be made from a polymeric acid that, by itself is non-wettable, but with selective additives it can be made wettable.

Examples of suitable polymeric backbones include, but are not limited to, polyolefins, polyacrylates, polymethacrylates, polyimides, polyamides, polyaramids, polyacrylamides, polystyrenes, and copolymers thereof, all of which are highly-fluorinated; in some embodiments, fully-fluorinated.

In one embodiment, the acidic groups are sulfonic acid groups or sulfonimide groups. A sulfonimide group has the formula:

—SO₂—NH—SO₂—R

where R is an alkyl group.

In one embodiment, the acidic groups are on a fluorinated side chain. In one embodiment, the fluorinated side chains are selected from alkyl groups, alkoxy groups, amido groups, ether groups, and combinations thereof, all of which are fully fluorinated.

In one embodiment, the HFAP has a highly-fluorinated olefin backbone, with pendant highly-fluorinated alkyl sulfonate, highly-fluorinated ether sulfonate, highly-fluorinated ester sulfonate, or highly-fluorinated ether sulfonimide groups. In one embodiment, the HFAP is a perfluoroolefin having perfluoro-ether-sulfonic acid side chains. In one embodiment, the polymer is a copolymer of 1,1-difluoroethylene and 2-(1,1-difluoro-2-(trifluoromethyl)allyloxy)-1,1,2,2-tetrafluoroethanesulfonic acid. In one embodiment, the polymer is a copolymer of ethylene and 2-(2-(1,2,2-trifluorovinyloxy)-1,1,2,3,3,3-hexafluoropropoxy)-1,1,2,2-tetrafluoroethanesulfonic acid. These copolymers can be made as the corresponding sulfonyl fluoride polymer and then can be converted to the sulfonic acid form.

In one embodiment, the HFAP is homopolymer or copolymer of a fluorinated and partially sulfonated poly(arylene ether sulfone). The copolymer can be a block copolymer.

In one embodiment, the HFAP is a sulfonimide polymer having Formula IX:

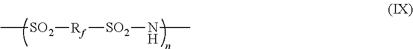

where:
R_{f} is selected from highly-fluorinated alkylene, highly-fluorinated heteroalkylene, highly-fluorinated arylene, and highly-fluorinated heteroarylene, which may be substituted with one or more ether oxygens; and
n is at least 4.

In one embodiment of Formula IX, R_{f} is a perfluoroalkyl group. In one embodiment, R_{f} is a perfluorobutyl group. In one embodiment, R_{f} contains ether oxygens. In one embodiment n is greater than 10.

In one embodiment, the HFAP comprises a highly-fluorinated polymer backbone and a side chain having Formula X:

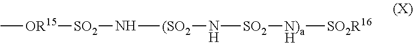

where:
R¹⁵ is a highly-fluorinated alkylene group or a highly-fluorinated heteroalkylene group;
R¹⁶ is a highly-fluorinated alkyl or a highly-fluorinated aryl group; and
a is 0 or an integer from 1 to 4.

In one embodiment, the HFAP has Formula XI:

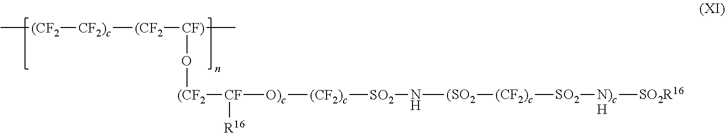

where:
R¹⁶ is a highly-fluorinated alkyl or a highly-fluorinated aryl group;
c is independently 0 or an integer from 1 to 3; and
n is at least 4.

The synthesis of HFAPs has been described in, for example, A. Feiring et al., J. Fluorine Chemistry 2000, 105, 129-135; A. Feiring et al., Macromolecules 2000, 33, 9262-9271; D. D. Desmarteau, J. Fluorine Chem. 1995, 72, 203-208; A. J. Appleby et al., J. Electrochem. Soc. 1993, 140(1), 109-111; and Desmarteau, U.S. Pat. No. 5,463,005.

In one embodiment, the HFAP also comprises a repeat unit derived from at least one highly-fluorinated ethylenically unsaturated compound. The perfluoroolefin comprises 2 to 20 carbon atoms. Representative perfluoroolefins include, but are not limited to, tetrafluoroethylene, hexafluoropropylene, perfluoro-(2,2-dimethyl-1,3-dioxole), perfluoro-(2-methylene-4-methyl-1,3-dioxolane), CF₂═CFO(CF₂)ₜCF═CF₂, where t is 1 or 2, and R_{f}″OCF═CF₂ wherein R_{f}″ is a saturated perfluoroalkyl group of from 1 to about ten carbon atoms. In one embodiment, the comonomer is tetrafluoroethylene.

In one embodiment, the HFAP is a colloid-forming polymeric acid. As used herein, the term “colloid-forming” refers to materials which are insoluble in water, and form colloids when dispersed into an aqueous medium. The colloid-forming polymeric acids typically have a molecular weight in the range of about 10,000 to about 4,000,000. In one embodiment, the polymeric acids have a molecular weight of about 100,000 to about 2,000,000. Colloid particle size typically ranges from 2 nanometers (nm) to about 140 nm. In one embodiment, the colloids have a particle size of 2 nm to about 30 nm. Any highly-fluorinated colloid-forming polymeric material having acidic protons can be used. Some of the polymers described hereinabove may be formed in non-acid form, e.g., as salts, esters, or sulfonyl fluorides. They will be converted to the acid form for the preparation of conductive compositions, described below.

In some embodiments, HFAP include a highly-fluorinated carbon backbone and side chains represented by the formula

—(O—CF₂CFR_{f}³)ₐ-O—CF₂CFR_{f}⁴SO₃E⁵

wherein R_{f}³ and R_{f}⁴ are independently selected from F, Cl or a highly-fluorinated alkyl group having 1 to 10 carbon atoms, a=0, 1 or 2, and E⁵. In some cases E⁵ can be a cation such as Li, Na, or K, and be converted to the acid form.

In some embodiments, the HFAP can be the polymers disclosed in U.S. Pat. No. 3,282,875 and in U.S. Pat. Nos. 4,358,545 and 4,940,525. In some embodiments, the HFAP comprises a perfluorocarbon backbone and the side chain represented by the formula

—O—CF₂CF(CF₃)—O—CF₂CF₂SO₃E⁵

where E⁵ is as defined above. HFAPs of this type are disclosed in U.S. Pat. No. 3,282,875 and can be made by copolymerization of tetrafluoroethylene (TFE) and the perfluorinated vinyl ether CF₂═CF—O—CF₂CF(CF₃)—O—CF₂CF₂SO₂F, perfluoro(3,6-dioxa-4-methyl-7-octenesulfonyl fluoride) (PDMOF), followed by conversion to sulfonate groups by hydrolysis of the sulfonyl fluoride groups and ion exchanged as necessary to convert them to the desired ionic form. An example of a polymer of the type disclosed in U.S. Pat. Nos. 4,358,545 and 4,940,525 has the side chain —O—CF₂CF₂SO₃E⁵, wherein E⁵ is as defined above. This polymer can be made by copolymerization of tetrafluoroethylene (TFE) and the perfluorinated vinyl ether CF₂═CF—O—CF₂CF₂SO₂F, perfluoro(3-oxa-4-pentenesulfonyl fluoride) (POPF), followed by hydrolysis and further ion exchange as necessary.

One type of HFAP is available commercially as aqueous Nafion® dispersions, from E. I. du Pont de Nemours and Company (Wilmington, Del.).

c. Preparation of Doped Electrically Conductive Polymer

The doped electrically conductive polymer is formed by oxidative polymerization of the precursor monomer in the presence of the HFAP in an aqueous medium. The polymerization has been described in published U.S. patent applications 2004/0102577, 2004/0127637, and 2005/0205860. The resulting product is an aqueous dispersion of the doped electrically conductive polymer.

In some embodiments, the pH of the dispersion is increased. The dispersions of doped conductive polymer remain stable from the as-formed pH of about 2, to neutral pH. The pH can be adjusted by treatment with cation exchange resins. In some embodiments, the pH is adjusted by the addition of aqueous base solution. Cations for the base can be, but are not limited to, alkali metal, alkaline earth metal, ammonium, and alkylammonium. In some embodiments, alkali metal is preferred over alkaline earth metal cations.

In some embodiments, the dispersion of the doped conductive polymer is blended with other water soluble or dispersible materials. Examples of types of materials which can be added include, but are not limited to polymers, dyes, coating aids, organic and inorganic conductive inks and pastes, charge transport materials, crosslinking agents, and combinations thereof. The other water soluble or dispersible materials can be simple molecules or polymers.

### 3. Second Layer of the Buffer Bilayer

The second layer of the buffer bilayer is in direct contact with the first layer. The second layer comprises inorganic nanoparticles selected from the group consisting of oxides, sulfides, and combinations thereof. In some embodiments, the second layer consists essentially of inorganic nanoparticles selected from the group consisting of oxides, sulfides, and combinations thereof. The inorganic nanoparticles can be insulative or semiconductive. As used herein, the term nanoparticles does not include emissive materials, such as phosphors.

The second layer of the buffer bilayer can be continuous or discontinuous. When the nanoparticles are semiconductive, the layer can be continuous or discontinuous. When the nanoparticles are insulative, it is preferred that the layer be discontinuous.

In some embodiments, the nanoparticles have a size of 50 nm or less; in some embodiments, 20 nm or less. The nanoparticles can have any shape. Some examples include, but are not limited to, spherical, elongated, chains, needle-shaped, core-shell nanoparticles, and the like.

Examples of semiconductive metal oxides include, but are not limited to mixed valence metal oxides, such as zinc antimonites and indium tin oxide, and non-stoichiometric metal oxides, such as oxygen deficient molybdenum trioxide, vanadium pentoxide, and the like.

Examples of insulative metal oxides include, but are not limited to, silicon oxide, titanium oxides, zirconium oxide, molybdenum trioxide, vanadium oxide, zinc oxide, samarium oxide, yttrium oxide, cesium oxide, cupric oxide, stannic oxide, aluminum oxide, antimony oxide, and the like.

Examples of metal sulfides include cadmium sulfide, copper sulfide, lead sulfide, mercury sulfide, indium sulfide, silver sulfide, cobalt sulfide, nickel sulfide, and molybdenum sulfide. Mixed metal sulfides such as Ni/Cd sulfides, Co/Cd sulfides, Cd/In sulfides, and Pd—Co—Pd sulfides may be used.

In some embodiments, the metal nanoparticles may contain both sulfur and oxygen.

Metal oxide nanoparticles can be made by reactive evaporation of metal in the presence of oxygen, by evaporation of selected oxide, and multi-component oxides, or by vapor-phase hydrolysis of inorganic compounds, for example silicon tetrachloride. It can also be produced by sol-gel chemistry using hydrolyzable metal compounds, particularly alkoxides of various elements, to react with either by hydrolysis and polycondensation to form multi-component and multi-dimensional network oxides.

Metal sulfide nanoparticles can be obtained by various chemical and physical methods. Some examples of physical methods are vapor deposition, lithographic processes and molecular beam epitaxy (MBE) of metal sulfides such as cadmium sulfide, (CdS), lead sulfide (PbS), zinc sulfide (ZnS), silver sulfide (Ag₂S), molybdenum sulfide (MoS₂) etc. Chemical methods for the preparation of metal sulfide nanoparticles are based on the reaction of metal ions in solution either with H₂S gas or Na₂S in aqueous medium.

In some embodiments, the nanoparticles are surface-treated with a surface modifier or coupling agent. The class of surface modifiers includes, but is not limited to, silanes, titanates, zirconates, aluminates, and polymeric dispersants. The surface modifiers contain chemical functionality, examples of which include, but are not limited, to nitrile, amino, cyano, alkyl amino, alkyl, aryl, alkenyl, alkoxy, aryloxy, sulfonic acid, acrylic acid, phosphoric acid, and alkali salts of the above acids, acrylate, sulfonates, amidosulfonate, ether, ether sulfonate, estersulfonate, alkylthio, arylthio, and the like.

In some embodiments, the surface modifiers contain crosslinking functionality, such as epoxy, alkylvinyl and arylvinyl groups. These groups can be introduced to react with the materials in adjacent layers. Examples of the surface modifiers with crosslinking groups include, but are not limited to, compounds 1-7 below.

compound 1: 3-Methacryloxypropyldimethylmethoxy silane

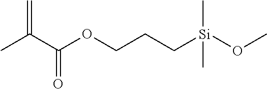

compound 2: 2-cinnamyloxyethyldimethylmethoxy silane

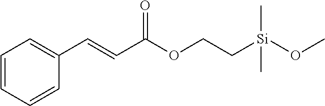

compound 3: 3-glycidoxypropyldimethylmethoxy silane

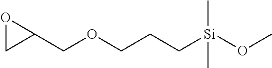

compound 4: (2-bicyclo[2.2.1]hept-5-en-2-ylethyl)dimethylmethoxy silane

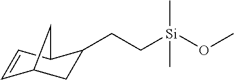

compound 5: [2-(3,4-Epoxycyclohexyl)ethyl]trimethoxy silane

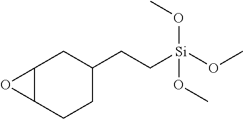

compound 6: allytrimethoxy silane

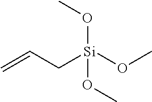

compound 7: (2-bicyclo[4.2.0]octa-1,3,5-trien-3-ylethenyl)trimethoxy silane

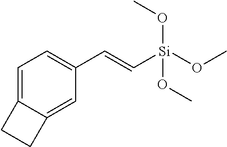

In one embodiment, the surface modifiers are fluorinated, or pefluorinated, such as tetrafluoro-ethyltrifluoro-vinyl-ether triethoxysilane, perfluorobutane-triethoxysilane, perfluorooctyltriethoxysilane, bis(trifluoropropyl)-tetramethyldisilazane, and bis (3-triethoxysilyl)propyl tetrasulfide.

Analogous zirconate and titanate coupling agents can also be used.

### 4. Formation of the Buffer Bilayer

The new buffer bilayer comprises:
a first layer comprising at least one electrically conductive polymer doped with at least one highly-fluorinated acid polymer, and
a second layer in contact with the first layer, the second layer comprising inorganic nanoparticles selected from the group consisting of oxides, sulfides, and combinations thereof.

In some embodiments, the buffer bilayer consists essentially of the first layer and the second layer, as described above.

In the following discussion, the conductive polymer, HFAP, and inorganic nanoparticles will be referred to in the singular. However, it is understood that more than one of any or all of these may be used.

The buffer bilayer is formed by first forming a layer of the doped electrically conductive polymer. This is then treated to form a discrete second layer of the inorganic nanoparticles.

The first layer is formed by liquid deposition of an aqueous dispersion of the doped conductive polymer. Any liquid deposition technique can be used, including continuous and discontinuous techniques. Continuous deposition techniques, include but are not limited to, spin coating, gravure coating, curtain coating, dip coating, slot-die coating, spray coating, and continuous nozzle printing or coating. Discontinuous deposition techniques include, but are not limited to, ink jet printing, gravure printing, and screen printing.

The first layer films thus formed are smooth and relatively transparent, and can have a conductivity in the range of 10⁻⁷ to 10⁻³ S/cm. The thickness of the first layer film can vary depending upon the intended use of the buffer bilayer. In some embodiments, the first layer has a thickness in the range of 10 nm to 200 nm; in some embodiments, 50 nm to 150 nm.

The second layer is then formed directly over and in contact with the first layer. The methods of making the second layer include, but are not limited to, priming of oxide or sulfide nanoparticles, reactive sputtering of a metal target, thermal evaporation of metal oxide or sulfide, atomic layer deposition of organometallic precursors of metal oxides, and the like.

In some embodiments, the second layer is formed by vapor deposition.

In some embodiments, the second layer is formed by liquid deposition of a dispersion of the nanoparticles in a liquid medium. The liquid medium can be aqueous or non-aqueous. In some embodiments, the nanoparticles are present in the dispersion from 0.1 to 2.0 wt %; in some embodiments, 0.1 to 1.0 wt %; in some embodiments, 0.1 to 0.5 wt %.

In some embodiments, the second layer is thinner than the first layer. In some embodiments, the thickness of the second layer is from a molecular monolayer to 75 nm.

In some embodiments, the second layer is discontinuous. By this it is meant that the nanoparticles are evenly distributed in the areas where they are deposited, but the concentration is insufficient to completely cover the first layer. In some embodiments, the coverage is less than about 90%. In some embodiments, the coverage is less than about 50%. The coverage should be at least 20%. In some embodiments, the coverage is between 20% and 50%. When the nanoparticles are insulative, it is preferred that the second layer be discontinuous.

In some embodiments, the nanoparticles are semiconductive and the second layer is continuous.

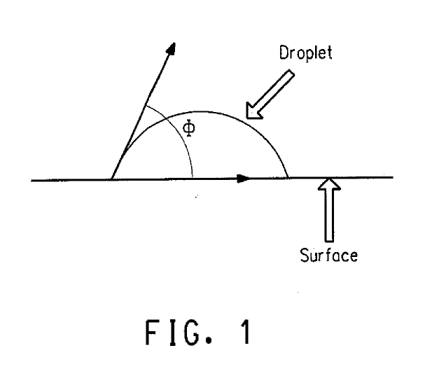

Buffer layers made from aqueous dispersions of electrically conductive polymers doped with fluorinated acids have been previously disclosed in, for example, published U.S. patent applications 2004/0102577, 2004/0127637, and 2005/0205860. These buffer layer, however, have a very low surface energy and it is difficult to coat additional layers over them when forming a device. The buffer layers described herein have a higher surface energy and are more easily coated. As used herein, the term “surface energy” is the energy required to create a unit area of a surface from a material. A characteristic of surface energy is that liquid materials with a given surface energy will not wet surfaces with a sufficiently lower surface energy. One way to determine the relative surface energies, is to compare the contact angle of a given liquid on layers of different materials. As used herein, the term “contact angle” is intended to mean the angle φ shown in FIG. 1. For a droplet of liquid medium, angle φ is defined by the intersection of the plane of the surface and a line from the outer edge of the droplet to the surface. Furthermore, angle φ is measured after the droplet has reached an equilibrium position on the surface after being applied, i.e. “static contact angle”. Higher contact angles indicate lower surface energies. A variety of manufacturers make equipment capable of measuring contact angles.

In one embodiment, the buffer bilayer as described herein, has a contact angle with a first liquid that is at least 5° lower than the contact angle with the same liquid on the first layer alone. In some embodiments, the buffer bilayer has a contact angle with toluene of less than 50°; in some embodiments, less than 40°.

### 5. Electronic Devices

In another embodiment of the invention, there are provided electronic devices comprising at least one electroactive layer positioned between two electrical contact layers, wherein the device further includes the new buffer layer. The term “electroactive” when referring to a layer or material is intended to mean a layer or material that exhibits electronic or electro-radiative properties. An electroactive layer material may emit radiation or exhibit a change in concentration of electron-hole pairs when receiving radiation.

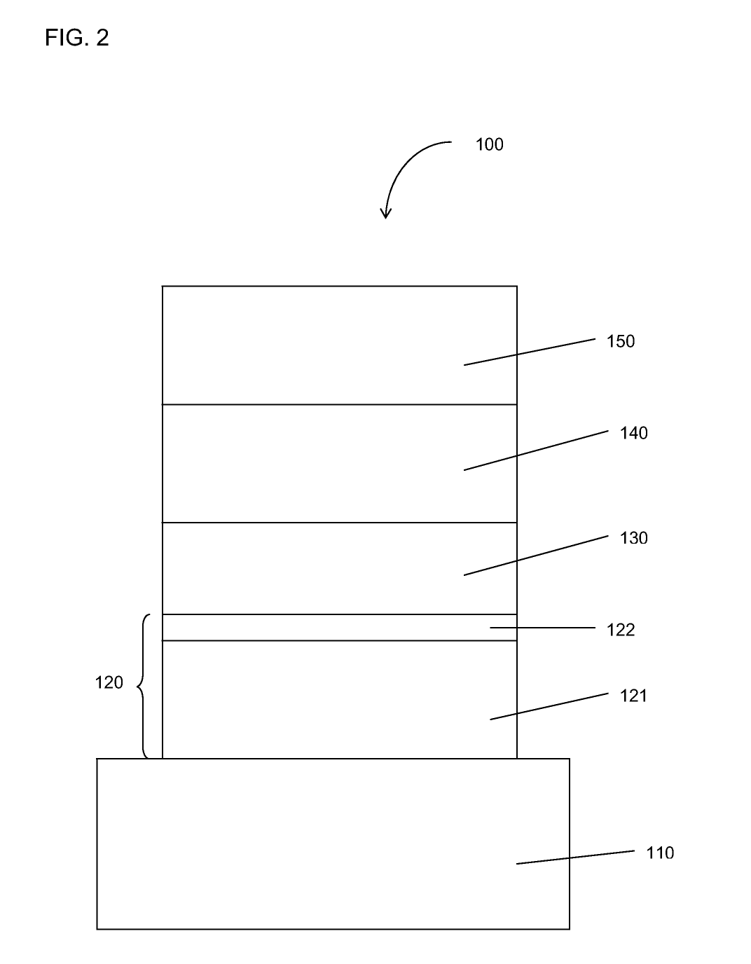

One example of a typical device is shown in FIG. 2. Device 100, has an anode layer 110, a buffer bilayer 120, an electroactive layer 130, and a cathode layer 150. Adjacent to the cathode layer 150 is an optional electron-injection/transport layer 140. The buffer bilayer has a first layer 121 and a second continuous layer 122.

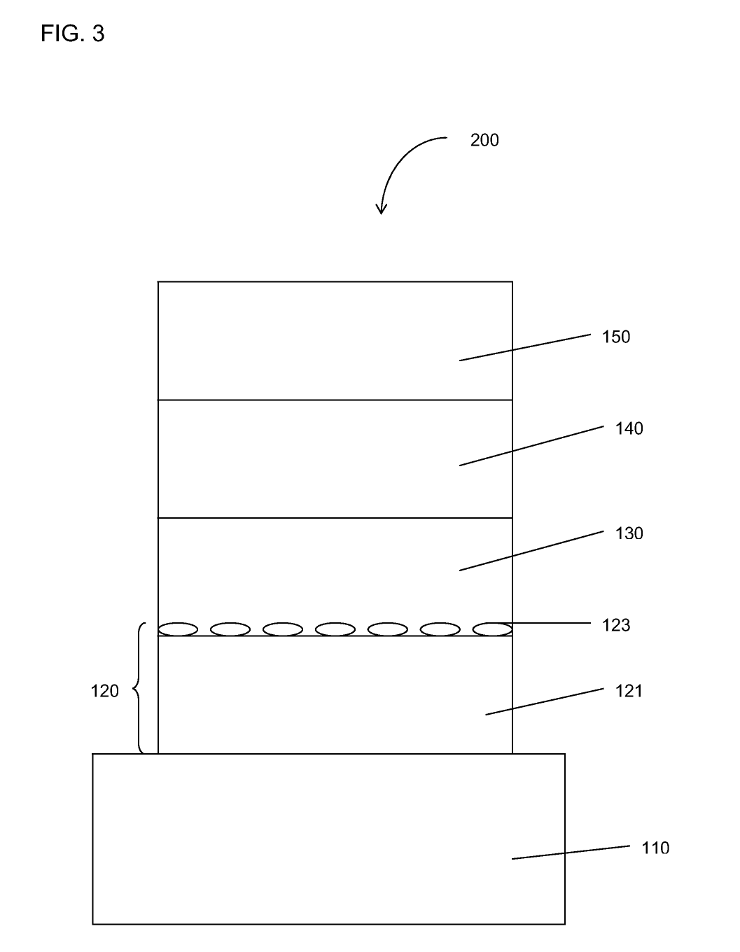

A second example of a typical device is shown in FIG. 3. Device 200, has an anode layer 110, a buffer bilayer 120, an electroactive layer 130, and a cathode layer 150. Adjacent to the cathode layer 150 is an optional electron-injection/transport layer 140. The buffer bilayer has a first layer 121 and a second discontinuous layer 123.

The devices may include a support or substrate (not shown) that can be adjacent to the anode layer 110 or the cathode layer 150. Most frequently, the support is adjacent to the anode layer 110. The support can be flexible or rigid, organic or inorganic. Examples of support materials include, but are not limited to, glass, ceramic, metal, and plastic films.

The anode layer 110 is an electrode that is more efficient for injecting holes compared to the cathode layer 150. The anode can include materials containing a metal, mixed metal, alloy, metal oxide or mixed oxide. Suitable materials include the mixed oxides of the Group 2 elements (i.e., Be, Mg, Ca, Sr, Ba, Ra), the Group 11 elements, the elements in Groups 4, 5, and 6, and the Group 8-10 transition elements. If the anode layer 110 is to be light transmitting, mixed oxides of Groups 12, 13 and 14 elements, such as indium-tin-oxide, may be used. As used herein, the phrase “mixed oxide” refers to oxides having two or more different cations selected from the Group 2 elements or the Groups 12, 13, or 14 elements. Some non-limiting, specific examples of materials for anode layer 110 include, but are not limited to, indium-tin-oxide (“ITO”), indium-zinc-oxide, aluminum-tin-oxide, gold, silver, copper, and nickel. The anode may also comprise an organic material, especially a conducting polymer such as polyaniline, including exemplary materials as described in “Flexible light-emitting diodes made from soluble conducting polymer,” Nature vol. 357, pp 477 479 (11 Jun. 1992). At least one of the anode and cathode should be at least partially transparent to allow the generated light to be observed.

The anode layer 110 may be formed by a chemical or physical vapor deposition process or spin-cast process. Chemical vapor deposition may be performed as a plasma-enhanced chemical vapor deposition (“PECVD”) or metal organic chemical vapor deposition (“MOCVD”). Physical vapor deposition can include all forms of sputtering, including ion beam sputtering, as well as e-beam evaporation and resistance evaporation. Specific forms of physical vapor deposition include rf magnetron sputtering and inductively-coupled plasma physical vapor deposition (“IMP-PVD”). These deposition techniques are well known within the semiconductor fabrication arts.

In one embodiment, the anode layer 110 is patterned during a lithographic operation. The pattern may vary as desired. The layers can be formed in a pattern by, for example, positioning a patterned mask or resist on the first flexible composite barrier structure prior to applying the first electrical contact layer material. Alternatively, the layers can be applied as an overall layer (also called blanket deposit) and subsequently patterned using, for example, a patterned resist layer and wet chemical or dry etching techniques. Other processes for patterning that are well known in the art can also be used.

The buffer layer 120 is the new bilayer described herein. In FIG. 2, the bilayer has a first layer 121 and a second continuous layer 122. In FIG. 3, the bilayer has a first layer 121 and a second discontinuous layer 123. Buffer layers made from conductive polymers doped with HFAPs, generally are not wettable by organic solvents. The buffer bilayers described herein can be more wettable and thus are more easily coated with the next layer from a non-polar organic solvent.

An optional layer, not shown, may be present between the buffer layer 120 and the electroactive layer 130. This layer may comprise hole transport materials. Examples of hole transport materials have been summarized for example, in Kirk-Othmer Encyclopedia of Chemical Technology, Fourth Edition, Vol. 18, p. 837-860, 1996, by Y. Wang. Both hole transporting molecules and polymers can be used. Commonly used hole transporting molecules include, but are not limited to: 4,4′,4″-tris(N,N-diphenyl-amino)-triphenylamine (TDATA); 4,4′,4″-tris(N-3-methylphenyl-N-phenyl-amino)-triphenylamine (MTDATA); N,N′-diphenyl-N,N′-bis(3-methylphenyl)-[1,1′-biphenyl]-4,4′-diamine (TPD); 1,1-bis[(di-4-tolylamino) phenyl]cyclohexane (TAPC); N,N′-bis(4-methylphenyl)-N,N′-bis(4-ethylphenyl)-[1,1′-(3,3′-dimethyl)biphenyl]-4,4′-diamine (ETPD); tetrakis-(3-methylphenyl)-N,N,N′,N′-2,5-phenylenediamine (PDA); α-phenyl-4-N,N-diphenylaminostyrene (TPS); p-(diethylamino)benzaldehyde diphenylhydrazone (DEH); triphenylamine (TPA); bis[4-(N,N-diethylamino)-2-methylphenyl](4-methylphenyl)methane (MPMP); 1-phenyl-3-[p-(diethylamino)styryl]-5-[p-(diethylamino)phenyl] pyrazoline (PPR or DEASP); 1,2-trans-bis(9H-carbazol-9-yl)cyclobutane (DCZB); N,N,N′,N′-tetrakis(4-methylphenyl)-(1,1′-biphenyl)-4,4′-diamine (TTB); N,N′-bis(naphthalen-1-yl)-N,N′-bis-(phenyl)benzidine (α-NPB); and porphyrinic compounds, such as copper phthalocyanine. Commonly used hole transporting polymers include, but are not limited to, polyvinylcarbazole, (phenylmethyl)polysilane, poly(dioxythiophenes), polyanilines, and polypyrroles. It is also possible to obtain hole transporting polymers by doping hole transporting molecules such as those mentioned above into polymers such as polystyrene and polycarbonate.

Depending upon the application of the device, the electroactive layer 130 can be a light-emitting layer that is activated by an applied voltage (such as in a light-emitting diode or light-emitting electrochemical cell), a layer of material that responds to radiant energy and generates a signal with or without an applied bias voltage (such as in a photodetector). In one embodiment, the electroactive material is an organic electroluminescent (“EL”) material, Any EL material can be used in the devices, including, but not limited to, small molecule organic fluorescent compounds, fluorescent and phosphorescent metal complexes, conjugated polymers, and mixtures thereof. Examples of fluorescent compounds include, but are not limited to, pyrene, perylene, rubrene, coumarin, derivatives thereof, and mixtures thereof. Examples of metal complexes include, but are not limited to, metal chelated oxinoid compounds, such as tris(8-hydroxyquinolato)aluminum (Alq3); cyclometalated iridium and platinum electroluminescent compounds, such as complexes of iridium with phenylpyridine, phenylquinoline, or phenylpyrimidine ligands as disclosed in Petrov et al., U.S. Pat. No. 6,670,645 and Published PCT Applications WO 03/063555 and WO 2004/016710, and organometallic complexes described in, for example, Published PCT Applications WO 03/008424, WO 03/091688, and WO 03/040257, and mixtures thereof. Electroluminescent emissive layers comprising a charge carrying host material and a metal complex have been described by Thompson et al., in U.S. Pat. No. 6,303,238, and by Burrows and Thompson in published PCT applications WO 00/70655 and WO 01/41512. Examples of conjugated polymers include, but are not limited to poly(phenylenevinylenes), polyfluorenes, poly(spirobifluorenes), polythiophenes, poly(p-phenylenes), copolymers thereof, and mixtures thereof.

Optional layer 140 can function both to facilitate electron injection/transport, and can also serve as a confinement layer to prevent quenching reactions at layer interfaces. More specifically, layer 140 may promote electron mobility and reduce the likelihood of a quenching reaction if layers 130 and 150 would otherwise be in direct contact. Examples of materials for optional layer 140 include, but are not limited to, metal chelated oxinoid compounds, such as bis(2-methyl-8-quinolinolato)(para-phenyl-phenolato)aluminum(III) (BAIQ) and tris(8-hydroxyquinolato)aluminum (Alq₃); tetrakis(8-hydroxyquinolinato)zirconium; azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; phenanthroline derivatives such as 9,10-diphenylphenanthroline (DPA) and 2,9-dimethyl-4,7-diphenyl-1,10-phenanthroline (DDPA); and any one or more combinations thereof. Alternatively, optional layer 140 may be inorganic and comprise BaO, LiF, Li₂O, or the like.

The cathode layer 150 is an electrode that is particularly efficient for injecting electrons or negative charge carriers. The cathode layer 150 can be any metal or nonmetal having a lower work function than the first electrical contact layer (in this case, the anode layer 110). As used herein, the term “lower work function” is intended to mean a material having a work function no greater than about 4.4 eV. As used herein, “higher work function” is intended to mean a material having a work function of at least approximately 4.4 eV.

Materials for the cathode layer can be selected from alkali metals of Group 1 (e.g., Li, Na, K, Rb, Cs,), the Group 2 metals (e.g., Mg, Ca, Ba, or the like), the Group 12 metals, the lanthanides (e.g., Ce, Sm, Eu, or the like), and the actinides (e.g., Th, U, or the like). Materials such as aluminum, indium, yttrium, and combinations thereof, may also be used. Specific non-limiting examples of materials for the cathode layer 150 include, but are not limited to, barium, lithium, cerium, cesium, europium, rubidium, yttrium, magnesium, samarium, and alloys and combinations thereof.

The cathode layer 150 is usually formed by a chemical or physical vapor deposition process. In some embodiments, the cathode layer will be patterned, as discussed above in reference to the anode layer 110.

Other layers in the device can be made of any materials which are known to be useful in such layers upon consideration of the function to be served by such layers.

In some embodiments, an encapsulation layer (not shown) is deposited over the contact layer 150 to prevent entry of undesirable components, such as water and oxygen, into the device 100. Such components can have a deleterious effect on the organic layer 130. In one embodiment, the encapsulation layer is a barrier layer or film. In one embodiment, the encapsulation layer is a glass lid.

Though not depicted, it is understood that the device 100 may comprise additional layers. Other layers that are known in the art or otherwise may be used. In addition, any of the above-described layers may comprise two or more sub-layers or may form a laminar structure. Alternatively, some or all of anode layer 110 the hole transport layer 120, the electron transport layer 140, cathode layer 150, and other layers may be treated, especially surface treated, to increase charge carrier transport efficiency or other physical properties of the devices. The choice of materials for each of the component layers is preferably determined by balancing the goals of providing a device with high device efficiency with device operational lifetime considerations, fabrication time and complexity factors and other considerations appreciated by persons skilled in the art. It will be appreciated that determining optimal components, component configurations, and compositional identities would be routine to those of ordinary skill of in the art.

In one embodiment, the different layers have the following range of thicknesses: anode 110, 500-5000 Å, in one embodiment 1000-2000Å; buffer layer 120, 50-2000 Å, in one embodiment 200-1000 Å; photoactive layer 130, 10-2000 Å, in one embodiment 100-1000 Å; optional electron transport layer 140, 50-2000 Å, in one embodiment 100-1000 Å; cathode 150, 200-10000 Å, in one embodiment 300-5000 Å. The location of the electron-hole recombination zone in the device, and thus the emission spectrum of the device, can be affected by the relative thickness of each layer. Thus the thickness of the electron-transport layer should be chosen so that the electron-hole recombination zone is in the light-emitting layer. The desired ratio of layer thicknesses will depend on the exact nature of the materials used.

In operation, a voltage from an appropriate power supply (not depicted) is applied to the device 100. Current therefore passes across the layers of the device 100. Electrons enter the organic polymer layer, releasing photons. In some OLEDs, called active matrix OLED displays, individual deposits of photoactive organic films may be independently excited by the passage of current, leading to individual pixels of light emission. In some OLEDs, called passive matrix OLED displays, deposits of photoactive organic films may be excited by rows and columns of electrical contact layers.

### EXAMPLES

### Example 1

This example illustrates the preparation of an aqueous dispersion of polypyrrole (PPy) made in the presence of Nafion® [Copolymer of TFE (tetrafluoroethylene) and PSEPVE (3,6-dioxa-4-methyl-7-octenesulfonic acid)]. This aqueous dispersion is to be used as a hole-injection conducting polymer as one part of the discrete bilayer.

In this example, an aqueous dispersion of Nafion® was prepared by heating poly(TFE/PSEPVE) having EW of 1000 in water to ˜270° C. The aqueous Nafion® dispersion had 25% (w/w) poly(TFE/PSEPVE) in water and was diluted to 11.5% with deionized water prior to the use for polymerization with pyrrole.

Pyrrole monomer was polymerized in the presence of the Nafion® dispersion as described in published U.S. patent application 2005-0205860. The polymerization ingredients have the following mole ratios: Nafion®/Pyrrole:3.4, Na₂S₂O₈/pyrrole:1.0, Fe₂(SO₄)₃/pyrrole:0.1. The reaction was allowed to proceed for 30 minutes. The aqueous PPy/poly(TFE-PSEPVE) dispersion was then pumped through three columns connected in series. The three columns contain Dowex® M-31, Dowex® M-43, and Dowex® M-31 Na+ respectively. The three Dowex® ion-exchange resins are from Dow Chemicals Company, Midland, Mich., USA. The ion-resin treated dispersion was subsequently microfluidized with one pass at 5,000 psi using a Microfluidizer Processor M-110Y (Microfluidics, Massachusetts, USA). The microfluidized dispersion was then filtered and degassed to remove oxygen. pH of the dispersion was measured to be 6.2 using a standard pH meter and solid % was determined to be 7.5% by a gravimetric method. Films spin-coated from the dispersion and then baked at 130° C. in air for 10 minutes have conductivity of 4.6×10⁻⁴/cm at room temperature.

### Example 2

This example illustrates the preparation of a discrete bilayer having a first layer of PPy/Nafion®-Poly(TFE-PSEPVE) and a second layer of mixed oxide nanoparticles. The example illustrates the effect of the mixed oxide layer on the wettability of the PPy/Nafion® surface.

Samples of a discrete bilayer of PPY/Nafion® and mixed oxide nanoparticles were made in the following manner. The PPY/Nafion® dispersion made in Example 1 was first diluted from 7.5% (w/w) in water to a lower concentration with a mixed solvent of water (75%, w/w), I-methoxy-2-propanol (15%, w/w), and 1-propanol (10%, w/w). The dilution combined with a spin-speed is aimed to achieving ˜25 nm (nano-meter) thickness of PPY/Nafion® on 50 nm ITO (indium/tin oxide) surface which was pre-treated with UV ozone for 10 minutes. The ITO purchased from Thin Film Devices Incorporated has sheet resistance of 50 ohms/square and 80% light transmission. The thin film PPY/Nafion® samples were then baked at 140° C. in air for 7 minutes. Part of the samples was used for top-coating with diluted ELCOM DU-1013TIV nanoparticle dispersion and the remaining were used as controls for wettability test with toluene and for blue emission device test.

The nanoparticle dispersion was obtained from Catalysts & Chemicals Industries Co., Ltd (Kanagawa, Japan). According to Materials Safety Data Sheet, the dispersion contains 25-35% (w/w) mixture of titanium dioxide, silicon dioxide, zirconium dioxide, and a silane coupling agent (trade secret) in a mixed dispersing liquid. The mixed dispersing media constitutes about 50-60% methyl-isobutyl-ketone (MIBK) and 10-20% methyl alcohol. Gravimetric analysis of ELCOM DU-1013TV (lot# 070516) dispersion shows that it contains 33.7% (w/w) mixed oxides. Two diluted dispersions of 0.1% (w/w) and 0.2% (w/w) were made by adding 0.0337 g ELCOM DU-1013TV to 9.9660 g MIBK, and 0.0579 g ELCOM DU-1013TV to 9.9472 g MIBK, respectively. The two dilute dispersions were used separately to spin-coat on the air-baked PPY/Nafion® at 3,000 rpm/second acceleration and at the speed for one minute. The bilayer samples of PPY/Nafion® and nanoparticles were then baked at 140° C. in air for 9 minutes.

Surfaces of PPY/Nafion® with and without the second layer of nanoparticles were imaged with Atomic Force Microscopy (AFM). Surface roughness (RMS) increases only from ˜2 nm to ˜4 nm as the result of the second layer of nanoparticles. The surfaces contain the mixed oxides having vertical height ranging from below 4 nm to ˜15 nm. The AFM images also show that particle coverage on surfaces made with the 0.1% dispersion (Sample 2-A) were much less dense than the surfaces made with the 0.2% dispersion (Sample 2-B). ESCA (Electron Spectroscopy for Chemical Analysis) shows that the mixed oxides consist of mainly titanium and silicon.

The wettability of the PPY/Nafion® with toluene was first carried out qualitatively by placing one droplet of toluene on the surfaces with and without the layer of nanoparticles. Toluene droplet balled up and quickly rolled away from the control PPY/Nafion® surface, but spread the entire surface of bilayer samples 2-A and 2-B. Table 2 illustrates the effect of the second layer on the contact angle of toluene. It also shows that wettability is improved with the second layer using the mixed oxide nanoparticles.

TABLE 2

| Sample | Contact Angle (degrees) |
|---|---|
| control PPy/Nafion ® | 50-52 |
| Sample 2-A | 45-46 |
| 0.1% dispersion | |
| Sample 2-A | 33-36 |
| 0.2% dispersion | |

### Example 3

This example illustrates the preparation of a discrete bilayer with a first layer of PPy/Nafion®-Poly(TFE-PSEPVE) and a second layer of colloidal silica. It also shows the effect of the oxide layer on the wettability of PPy/Nafion® surface.

Samples of a discrete bilayer of PPY/Nafion® and colloidal silica for wettability and blue emission device test were made in the following manner. Samples of PPY/Nafion® films on ITO prior to forming the second layer with colloidal silica were made first according to the procedure described in Example 2. Part of samples was used for forming a bilayer with colloidal silica and the remaining as controls for wettability with toluene and blue emission device tests. Colloidal silica used in this example is MIBK-ST obtained from Nissan Chemical USA, Houston, Tex. According to Materials Safety Data Sheet, the dispersion contains 30-31% (w/w) amorphous silica and 1% (w/w) additive (trade secret) in 69-68% (w/w) methyl-isobutyl-ketone (MIBK). The particle size range is stated to be from 10 to 15 nm. Gravimetric analysis of the MIBK-ST used in this example contains 31.2% (w/w) solid. Two diluted silica colloidal dispersions of 0.13% (w/w) and 0.25% (w/w) were made by adding 0.0401 g MIBK-ST to 9.9413 g MIBK, and 0.0792 g MIBK-ST to 9.962 g MIBK, respectively. The two dilute dispersions were used separately to spin-coat on the baked PPY/Nafion® at 3,000 rpm/second acceleration and at the speed for one minute. The bilayer samples of PPY/Nafion® and silica nanoparticles were then baked at 140° C. in air for 9 minutes.

Surfaces of PPY/Nafion® without a second layer (control), the surface with a bilayer made with 0.13% silica dispersion (Sample 3-A) and surface of a bilayer made with 0.25% silica dispersion (Sample 3-B) were compared for film quality and surface roughness by a optical microscope magnified at 500× and profilometry. There was no discernable difference between the control and Sample 3-A and 3-B surfaces. There was also no visible difference in film thickness. Wettability of the PPY/Nafion® with toluene was carried out qualitatively by placing one droplet of toluene on the surfaces with and without a second layer of colloidal silica. Toluene droplet balled up and quickly rolled away from the control PPY/Nafion® surface, but spread over the entire surface bilayers 3-A and 3-B. This qualitative test shows that wettability is improved with a second layer formed using the colloidal silica.

### Example 4

This example illustrates the fabrication and performance of deep blue emitting diodes using PPY/Nafion® alone as a buffer layer and buffer bilayers made with PPY/Nafion and mixed oxide nanoparticles.

The ITO/PPY/Nafion® samples prepared in Example 2 were used to make deep blue emission devices. The ITO/PPY/Nafion® control and Samples 2-A and 2-B were top-coated in an inert chamber with a dilute toluene solution of a hole transport polymer which is a crosslinkable copolymer of a dialkylfluorene and triphenylamine. The coating had a 20 nm thickness after baking at 270° C. for 30 mins. The baking is to remove solvent and to crosslink the polymer to be insoluble in the solvent of the next layer solution processing. After cooling, the substrates were spin-coated with an emissive layer solution containing 13:1 fluorescent host:blue fluorescent dopant (48 nm), and subsequently heated at 115° C. for 20 mins to remove solvent. The layer thickness was approximately 48 nm. The substrates were then masked and placed in a vacuum chamber. A 20 nm thick layer of ZrQ [tetrakis-(8-hydroxyquinoline) zirconium] as an electron transport layer was deposited by thermal evaporation, followed by a 0.5 nm layer of LiF and 100 nm aluminum cathode layer.

The OLED samples were characterized by measuring their (1) current-voltage (I-V) curves, (2) electroluminescence radiance versus voltage, and (3) electroluminescence spectra versus voltage. All three measurements were performed at the same time and controlled by a computer. The current efficiency (cd/A) of the device at a certain voltage is determined by dividing the electroluminescence radiance of the LED by the current density needed to run the device. The power efficiency (Lm/W) is the current efficiency divided by the operating voltage. The results are shown in Table 3. The results show that using a bilayer buffer did not significantly decrease device performance relative to the control buffer layer with respect to device voltage, color, efficiency, and lifetime. The device made with buffer bilayer Sample 2-B did have a slight loss of efficiency and 10% loss of lifetime. This data suggests that the weight % of the mixed oxide nanoparticles should be kept to no more than 0.2%.

TABLE 3
Device results with second layer of mixed oxide nanoparticles

| Buffer Layer | QE | CIEY | V (v) | Lm/W | T50 (h) |
|---|---|---|---|---|---|
| control | 3.9% | 0.136 | 5.2 | 2.6 | 3432 |
| Bilayer Sample 2-A | 3.8% | 0.137 | 5.2 | 2.6 | 3589 |
| Bilayer Sample 2-B | 3.5% | 0.136 | 5.2 | 2.4 | 3185 |

All data @ 1000 nits, QE = quantum efficiency; CIEY = y color coordinate according to the C.I.E. chromaticity scale (Commision Internationale de L'Eclairage, 1931); Lm/W = luminance per watt; T50(h) = time to half luminance in hours @ 24° C.

### Example 5

This example illustrates the fabrication and performance of deep blue emitting diodes using PPY/Nafion® alone as a buffer layer and buffer bilayers made with PPY/Nafion and colloidal silica nanoparticles.

The ITO/PPY/Nafion® samples prepared in Example 3 were used to make deep blue emission devices. The ITO/PPY/Nafion® control and Samples 3-A and 3-B were then fabricated into the deep blue emission devices using the same materials and same fabrication conditions as in Example 4, and tested as described in Example 4. The device performance results are summarized in Table 4. The results show that using a bilayer buffer did not significantly decrease device performance relative to the control buffer layer with respect to device voltage, color, efficiency, and lifetime. The device made with buffer bilayer Sample 3-B did have a slight loss change in color. This data suggests that the weight % of the silica nanoparticles should be kept to no more than 0.3%.

TABLE 4
Device results with second layer of silica

| Buffer layer | QE | CIEY | V (v) | Lm/W | T50 (h) |
|---|---|---|---|---|---|
| control | 3.7% | 0.149 | 5.5 | 2.5 | 4290 |
| Bilayer Sample 3-A | 3.5% | 0.149 | 5.4 | 2.4 | 3828 |
| Bilayer Sample 3-B | 3.6% | 0.157 | 5.4 | 2.5 | 4337 |

All data @ 1000 nits, QE = quantum efficiency; CIEY = y color coordinate according to the C.I.E. chromaticity scale (Commision Internationale de L'Eclairage, 1931); Lm/W = luminance per watt; T50(h) = time to half luminance in hours @ 24° C.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination.

The use of numerical values in the various ranges specified herein is stated as approximations as though the minimum and maximum values within the stated ranges were both being preceded by the word “about.” In this manner slight variations above and below the stated ranges can be used to achieve substantially the same results as values within the ranges. Also, the disclosure of these ranges is intended as a continuous range including every value between the minimum and maximum average values including fractional values that can result when some of components of one value are mixed with those of different value. Moreover, when broader and narrower ranges are disclosed, it is within the contemplation of this invention to match a minimum value from one range with a maximum value from another range and vice versa.

What is claimed is:

1. A buffer bilayer comprising:
a first layer comprising at least one electrically conductive polymer doped with at least one highly-fluorinated acid polymer, and
a second layer comprising inorganic nanoparticles selected from the group consisting of oxides, sulfides and combinations thereof.

2. The buffer bilayer of claim 1, wherein the inorganic nanoparticles are semiconductive and the second layer is continuous.

3. The buffer bilayer of claim 1, wherein the second layer is discontinuous.

4. The bilayer of claim 1, wherein the electrically conductive polymer is selected from the group consisting of polythiophenes, poly(selenophenes), poly(tellurophenes), polypyrroles, polyanilines, polycyclic aromatic polymers, copolymers thereof, and combinations thereof.

5. The bilayer of claim 4, wherein the electrically conductive polymer is selected from the group consisting of a polyaniline, polythiophene, a polypyrrole, a poly(4-amino-indole), a poly(7-amino-indole), a polymeric fused polycyclic heteroaromatic, copolymers thereof, and combinations thereof.

6. The bilayer of claim 5, wherein the electrically conductive polymer is selected from the group consisting of unsubstituted polyaniline, poly(3,4-ethylenedioxythiophene), poly(3,4-ethyleneoxythiathiophene), poly(3,4-ethylenedithiathiophene), unsubstituted polypyrrole, poly(thieno(2,3-b)thiophene), poly(thieno(3,2-b)thiophene), and poly(thieno(3,4-b)thiophene).

7. The bilayer of claim 1, wherein the highly-fluorinated acid polymer is at least 95% fluorinated.

8. The bilayer of claim 1, wherein the highly-fluorinated acid polymer is selected from a sulfonic acid and a sulfonimide.

9. The bilayer of claim 1, wherein the highly-fluorinated acid polymer is a perfluoroolefin having perfluoro-ether-sulfonic acid side chains.

10. The bilayer of claim 1, wherein the highly-fluorinated acid polymer is selected from the group consisting of a copolymer of 1,1-difluoroethylene and 2-(1,1-difluoro-2-(trifluoromethyl)allyloxy)-1,1,2,2-tetrafluoroethanesulfonic acid and a copolymer of ethylene and 2-(2-(1,2,2-trifluorovinyloxy)-1,1,2,3,3,3-hexafluoropropoxy)-1,1,2,2-tetrafluoroethanesulfonic acid.

11. The bilayer of claim 1, wherein the highly-fluorinated acid polymer is selected from a copolymer of tetrafluoroethylene and perfluoro(3,6-dioxa-4-methyl-7-octenesulfonic acid), and a copolymer of tetrafluoroethylene and perfluoro(3-oxa-4-pentenesulfonic acid).

12. The bilayer of claim 1, wherein the nanoparticles are selected from the group consisting of zinc antimonites, indium tin oxide, oxygen-deficient molybdenum trioxide, vanadium pentoxide, and combinations thereof.

13. The bilayer of claim 1, wherein the nanoparticles are selected from the group consisting of silicon oxides, titanium oxides, zirconium oxide, molybdenum trioxide, vanadium oxide, aluminum oxide, zinc oxide, samarium oxide, yttrium oxide, cesium oxide, cupric oxide, stannic oxide, aluminum oxide, antimony oxide, and combinations thereof.

14. The bilayer of claim 1, wherein the inorganic nanoparticles are selected from the group consisting of cadmium sulfide, copper sulfide, lead sulfide, mercury sulfide, indium sulfide, silver sulfide, cobalt sulfide, nickel sulfide, molybdenum sulfide, Ni/Cd sulfides, Co/Cd sulfides, Cd/In sulfides, and Pd-Co-Pd sulfides.

15. The bilayer of claim 1, wherein the nanoparticles are surface-treated with a surface modifier.

16. The bilayer of claim 15, wherein the surface modifier is selected from the group consisting of silanes, titanates, zirconates, aluminates, and polymeric dispersants.

17. The bilayer of claim 16, wherein the surface modifier has crosslinking functionality.

18. The bilayer of claim 15, wherein the surface modifier is selected from group consisting of Compound 1 through Compound 7 below:
compound 1: 3-Methacryloxypropyldimethylmethoxy silane 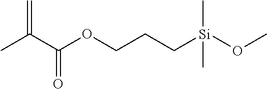
compound 2: 2-cinnamyloxyethyldimethylmethoxy silane 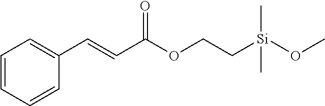
compound 3: 3-glycidoxypropyldimethylmethoxy silane 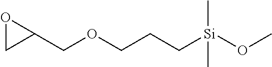
compound 4: (2-bicyclo[2.2.1]hept-5-en-2-ylethyl)dimethylmethoxy silane 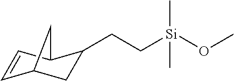
compound 5: [2-(3,4-Epoxycyclohexyl)ethyl]trimethoxy silane 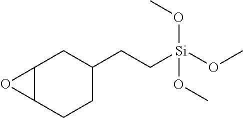
compound 6: allytrimethoxy silane 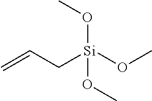
compound 7: (2-bicyclo[4.2.0]octa-1,3,5-trien-3-ylethenyl)trimethoxy silane

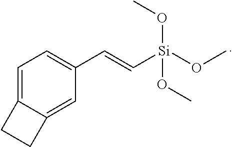

19. An electronic device comprising the buffer bilayer of claim 1.

20. The device of claim 19, further comprising an anode, an electroactive layer, and a cathode, wherein the buffer bilayer is positioned between the anode and the electroactive layer.
